(19) United States
(12) Patent Application Publication
(10) Pub. No.: US 2002/0175772 A1
(43) Pub. Date: Nov. 28, 2002

(54) Power efficient delay stage for a voltage-controlled oscillator

(75) Inventors: Sasan Cyrusian, Scotts Valley, CA (US); Michael A. Ruegg, Santa Cruz, CA (US)

Correspondence Address: BRINKS HOFER GILSON & LIONE, P.O. BOX 10395, CHICAGO, IL, 60611, US

(73) Assignee: Infineon Technologies North America Corp.

(21) Appl. No.: 09/865,754

(22) Filed: May 25, 2001

(51) Int. Cl. H03B 5/02; H03H 11/26

(52) U.S. Cl. 331/57; 331/177 R; 327/278; 327/280

(57) ABSTRACT

A delay stage for inclusion in a semiconductor device is well suited for incorporation in a voltage-controlled oscillator for maximizing the peak-to-peak output voltage and enhancing immunity to noise. The delay stage comprises a first amplifier having a first input terminal and a supply terminal for receiving a minimum rail voltage. A second amplifier has a second input terminal and a supply terminal for receiving the minimum rail voltage. A cascade feedback amplifier is coupled to the first amplifier and the second amplifier. The cascade feedback amplifier has a first output and a second output for providing an output voltage between or approximately equal to at least one of a maximum rail voltage and the minimum rail voltage. A current controller is arranged to vary a resistive load presented to the cascade feedback amplifier. The resistive load is associated with a current flowing to or from the maximum voltage rail.

### FIELD OF THE INVENTION

This invention relates to a power efficient delay stage for a voltage-controlled oscillator.

### BACKGROUND

In the prior art, a delay stage may include a tail current source and an active load. For example, the tail current source may provide a suitable current through a resistor or an active load. However, the voltage drop through the tail current source limits the conventional peak-to-peak output voltage to some amount less than a rail-to-rail peak output voltage. In turn, the reduction in the peak-to-peak output voltage tends to make an oscillator that incorporates a delay stage with a tail current source more susceptible to noise than it otherwise would be. Further, the tail current source may represent an additional noise source itself. Thus, a need exists for improving the noise immunity of a delay stage for incorporation into an oscillator.

In the prior art, a voltage-controlled oscillator (VCO) may use three or more complementary metal oxide (CMOS) semiconductor delay stages. Each delay stage may add jitter to the output waveform. Jitter refers to short-term variations or timing discrepancies in the output waveform with respect to a reference clock signal. Jitter may be caused by noise that distorts the waveform and interferes with optimum timing of the digital system. Therefore, it would be desirable to minimize the number of delay stages required to provide a reliable voltage-controlled oscillator to reduce jitter in the output waveform of the oscillator.

### SUMMARY

In accordance with the invention, a delay stage for inclusion in a semiconductor device is well suited for incorporation in a voltage-controlled oscillator for maximizing the peak-to-peak output voltage and enhancing immunity to noise. The delay stage comprises a first amplifier having a first input terminal and a supply terminal for receiving a minimum rail voltage. A second amplifier has a second input terminal and a supply terminal for receiving the minimum rail voltage. A cascade feedback amplifier is coupled to the first amplifier and the second amplifier. The cascade feedback amplifier has a first output and a second output for providing an output voltage between or approximately equal to at least one of a maximum rail voltage and the minimum rail voltage. A current controller is arranged to vary a resistive load presented to the cascade feedback amplifier. The resistive load is associated with a current flowing to or from the maximum voltage rail.

### BRIEF DESCRIPTION OF THE DRAWINGS

FIG. 1 is a schematic diagram of a first embodiment of a delay stage in accordance with the invention.

FIG. 2 is a schematic diagram of a second embodiment of a delay stage in accordance with the invention.

FIG. 3 is a block diagram illustrating how two delay stages may be cascaded to form a voltage-controlled ring oscillator.

FIG. 4 is a schematic diagram of a voltage-controlled oscillator ring that incorporates the delay stages of FIG. 2 in accordance with the invention.

FIG. 5 illustrates the output waveform of the voltage-controlled oscillator of FIG. 4.

FIG. 6 illustrates a graph of frequency versus control voltage for a voltage-controlled oscillator that uses a delay stage of FIG. 1 and another voltage-controlled oscillator that uses a delay stage of FIG. 2.

### DETAILED DESCRIPTION

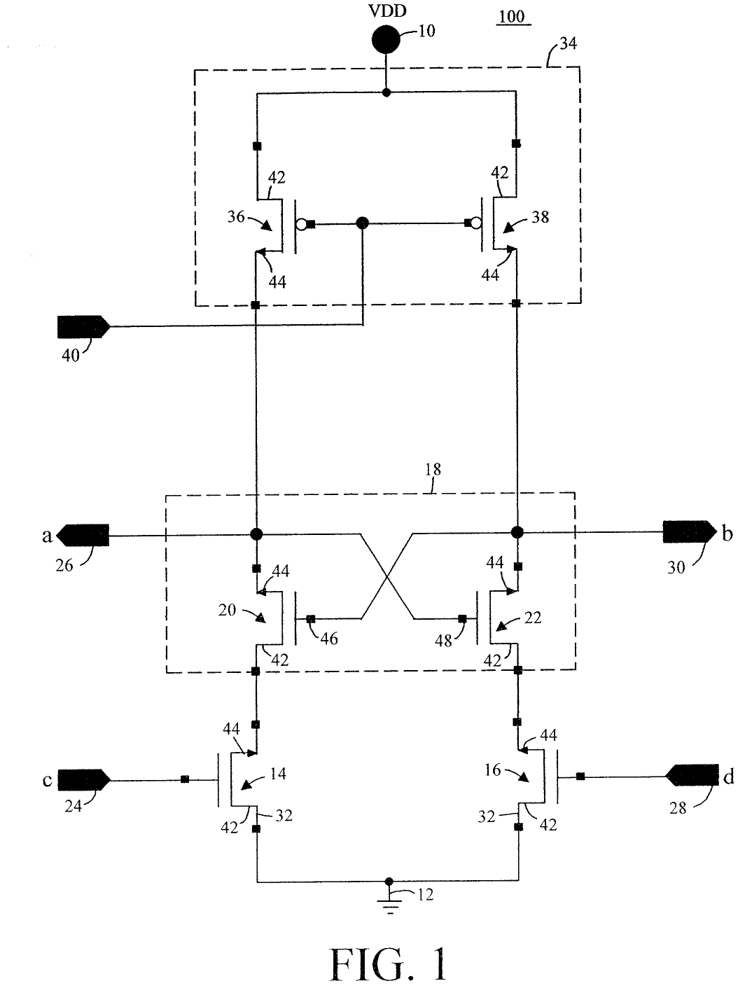

In accordance with the invention, FIG. 1 discloses a first embodiment of a delay stage 100 for inclusion in a voltage-controlled oscillator. A delay stage 100 comprises a first amplifier 14 having a first input terminal 24 and a supply terminal 32 for receiving a minimum rail voltage 12. A second amplifier 16 has a second input terminal 28 and a supply terminal 32 for receiving the minimum rail voltage 12. A cascade feedback amplifier 18 is coupled to the first amplifier 14 and the second amplifier 16. The cascade feedback amplifier 18 has a first output terminal 26 and a second output terminal 30 for providing an output voltage between or approximately equal to at least one of a maximum rail voltage 10 (e.g., VDD) and the minimum rail voltage 12 (e.g., VSS or ground). A current controller 34 is arranged to vary a resistive load presented to the cascade feedback amplifier 18. The resistive load is associated with a current flowing to or from the maximum voltage rail 10.

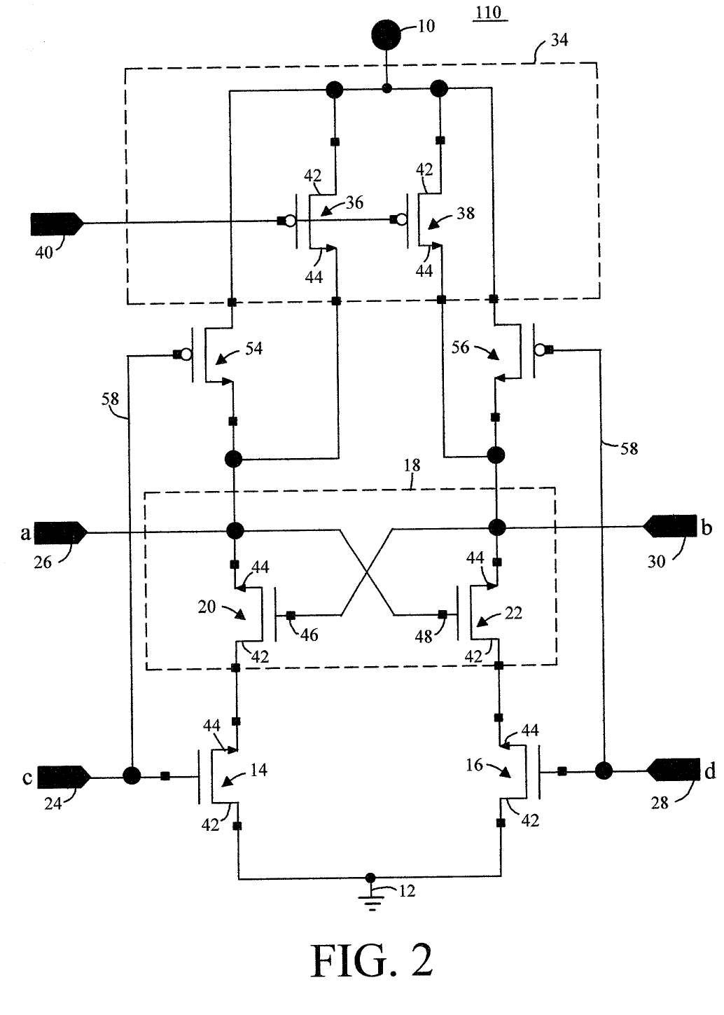

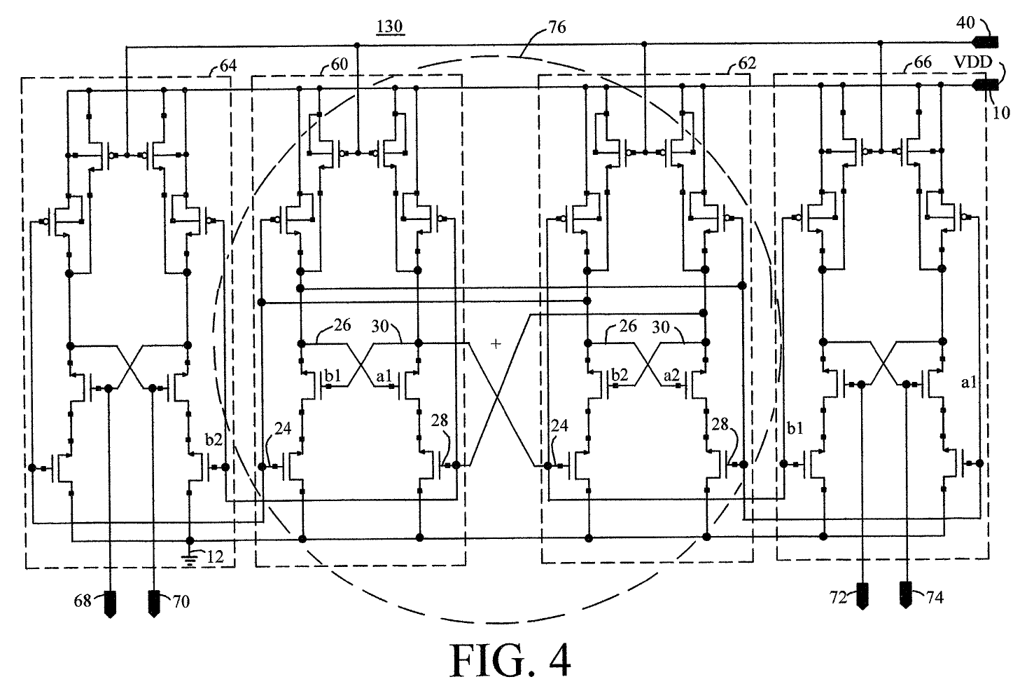

In one embodiment, the first amplifier 14 comprises a first N-type metal oxide transistor (NMOS) having a gate as the first input terminal 24 and a source as the supply terminal 32. Similarly, the second amplifier 16 comprises a second NMOS transistor having a gate as the second input terminal 28 and a source as the supply terminal 32. As shown throughout FIG. 1, FIG. 2 and FIG. 4, the lead of the transistor with the arrow indicates the drain 44 and the lead without the arrow indicates the source 42, contrary to the traditional convention. Any transistor in FIG. 1, FIG. 2, and FIG. 4 may be fabricated so that the drain region and the source region of the transistor are substantially, physically identical or interchangeable. The drains 44 of the first NMOS transistor and the second NMOS transistor are coupled to the cascade feedback amplifier 18.

In one embodiment, the cascade amplifier 18 comprises a primary transistor 20 coupled to a secondary transistor 22 such that a primary gate 46 of the primary transistor 20 is coupled to a second output terminal 30 associated with the secondary transistor 22. Further, the secondary gate 48 of the secondary transistor 22 is coupled to a first output terminal 26 associated with the primary transistor 20. Accordingly, the output of the first output terminal 26 of the primary transistor 20 provides an input that turns on or off the secondary transistor 22 and the output of the second output terminal 30 of the secondary transistor 22 provides an input that turns on or off the primary transistor 20. The primary transistor 20 and the secondary transistor 22 may comprise NMOS devices as shown or other types of semiconductor devices. As shown in FIG. 1, the source of the primary transistor 20 is coupled to the drain 44 of the first transistor 14; the source 42 of the secondary transistor 22 is coupled to the drain 44 of the second transistor 16. The drains 44 of the primary transistor 20 and the secondary transistor 22 are coupled to the current controller 34.

In accordance with one embodiment, the current controller 34 comprises at least one current-regulating transistor (e.g., 36, 38) with a source-drain path coupled between the maximum voltage rail 10 and the cascade amplifier 18. A first current-regulating transistor 36 has a gate that is coupled to a control voltage terminal 40, a drain 44 that is coupled to the first output terminal 26, and a source 42 that is coupled to a maximum rail voltage 10 or maximum voltage rail source. The second current-regulating transistor 38 has a gate that is coupled to a control voltage terminal 40, a drain that is coupled to a second output terminal 30, and a source that is coupled to maximum rail voltage 10 source. As shown in FIG. 1, the first current-regulating transistor 36 and the second current-regulating transistor 38 comprise PMOS (P-type metal oxide semiconductor) transistors.

Although the first amplifier 14, the second amplifier 16 and the cascade feedback amplifier 18 use NMOS transistors and the current controller 34 uses PMOS transistors in FIG. 1, in alternate embodiment of the delay stage 100 the first amplifier 14, the second amplifier 16, and the cascade feedback amplifier 18 may use PMOS transistors and the current controller 34 may use NMOS transistors with the polarity of the biasing voltages being reversed relative to those required in FIG. 1.

The minimum rail voltage 12 terminal may represent VSS or ground, while the maximum rail voltage 10 may represent VDD. The first amplifier 14 provides the minimum voltage rail to the primary transistor 20 of the cascade feedback amplifier 18 in response to the application of a proper biasing voltage applied to the first input terminal 24. Likewise, the second amplifier 16 provides the minimum voltage rail to the secondary transistor 22 of the cascade feedback amplifier 18 in response to the application of a proper biasing voltage applied to the second input terminal 28. Accordingly, the first input terminal 24 controls first amplifier 14 to enable or disable the primary transistor 20; the second input terminal 28 controls second amplifier 16 to enable or disable the secondary transistor 22 of the cascade feedback amplifier 18. If the primary transistor 20 is on or enabled, the first output terminal 26 may approach or be approximately equal to the minimum output rail voltage 12. Similarly, if the secondary transistor 22 is on or enabled the second output terminal 30 may approach or be approximately equal to the minimum output rail voltage 12.

In contrast, if the primary transistor 20 is off, the first output voltage at the first output terminal 26 may approach the maximum rail voltage 10 less any voltage drop through the current controller 34; if the secondary transistor 22 is off, the second output voltage at the second output terminal 30 may approach the maximum rail voltage 10 less any voltage drop through the current controller 34. The primary transistor 20 is on when the secondary transistor 22 is off, and vice versa, to produce an out-of-phase relationship with respect to a first output waveform of the first output terminal 26 with respect to a second output waveform of the second output terminal 30. The interconnection of the primary transistor 20 and the secondary transistor 22 is consistent with the out-of-phase relationship. The first output terminal 26 and the second output terminal 30 produce output voltages that are approximately one-hundred and eighty degrees out of phase with respect to one another. The first input terminal 24 and the second input terminal 28 are switched on and off to produce an oscillatory first output waveform at the first output terminal 26 and an oscillatory second output waveform at the second output terminal 30.

The oscillatory first output signal at the first output terminal 26 and an oscillatory second output signal at the second output terminal 30 each fall between or approximately equal at least one of the minimum rail voltage 12 and the maximum rail voltage 10. The first output signal at the first output terminal 26 may be less than the maximum rail voltage 10 by an amount of a voltage drop in a source-drain path of the first current-regulating transistor 36. The second output signal at the second output terminal 30 may be less than the maximum rail voltage 10 by an amount of a voltage drop in a source-to-drain path of the second current-regulating transistor 38. The first output signal may fall short of reaching the minimum rail voltage 12 by an amount of a voltage drop in a source-drain path of a first amplifier 14. The second output signal may fall short of reaching the minimum rail voltage 12 by an amount of the voltage drop in a source-drain path of the second amplifier 16. Because the voltage drop in the source-drain paths of the foregoing CMOS, NMOS and PMOS transistors may be less than 0.1 volts for practical semiconductor devices, the delay stage of FIG. 1 can provide output voltages swings that approach or equal the maximum rail voltage 10 and the minimum rail voltage 12 less any insignificant source-drain voltage drop. By maximizing the peak-to-peak voltage swing at the first output terminal 26 and the second output terminal 30, the delay stage has enhanced immunity to noise and jitter that might otherwise interfere with the reliability of a voltage-controlled oscillator or dependent digital circuitry thereon. The delay stage of FIG. 1 may be applied to gain switching in a voltage-controlled oscillator, where the first current-regulating transistor 36 and the second-current regulating transistor 38 are separately switched to control the voltage applied to the cascade feedback amplifier 18 from the maximum rail voltage 10. Accordingly, the gain of the output voltages at the first output terminal and the second output terminal are controlled by the first current-regulating transistor 36, the second current-regulating transistor, 38 or both.

In one embodiment, the maximum rail voltage and the minimum rail voltage may represent regulated supply voltages.

FIG. 2 shows another delay circuit which is similar to the delay circuit of FIG. 1, except the delay circuit of FIG. 2 includes at least one oscillation-enhancing transistor. Like elements are indicated by like reference numbers in FIG. 1 and FIG. 2.

As shown in FIG. 2, two oscillation-enhancing transistors (54,56) support the provision of an oscillator with a greater bandwidth than otherwise possible. A first oscillation-enhancing transistor 54 has a control input 58 coupled to the first input terminal 24. A controlled path (e.g., source-drain path) of the first oscillation-enhancing transistor 54 is coupled in parallel with a source-drain path of the first current-regulating transistor 36. The controlled path is coupled between the maximum voltage rail 10 the cascade amplifier 18. A second oscillation-enhancing transistor 56 has a control input 58 coupled to the second input terminal 30. A controlled path (e.g., source-drain path) of the second oscillation-enhancing transistor 56 is coupled in parallel with a source-drain path of the second current-regulating transistor 38.

In one embodiment, a first oscillation-enhancing transistor 54 provides the maximum rail voltage 10 to the first output terminal 26 and a second oscillation-enhancing transistor 56 provides the maximum rail voltage 10 to the second output terminal 30, even if an insufficient control voltage is applied to turn on the transistors (36, 38) of the current controller 34. The insufficient control voltage may be less than an gate-to-source threshold voltage of the first current-regulating transistor 36 or the second current regulating transistor 38, for example. However, the delay stage 110 of FIG. 2 supports oscillation when the control voltage is less than a minimum threshold control voltage, whereas the delay stage 100 of FIG. 1 does not support oscillation when the control voltage is less than a minimum threshold control voltage. Further, the duty cycle of the output signals are more symmetrical than the output signals of FIG. 1 with the addition of the oscillation-enhancing transistors (54,56) of FIG. 2.

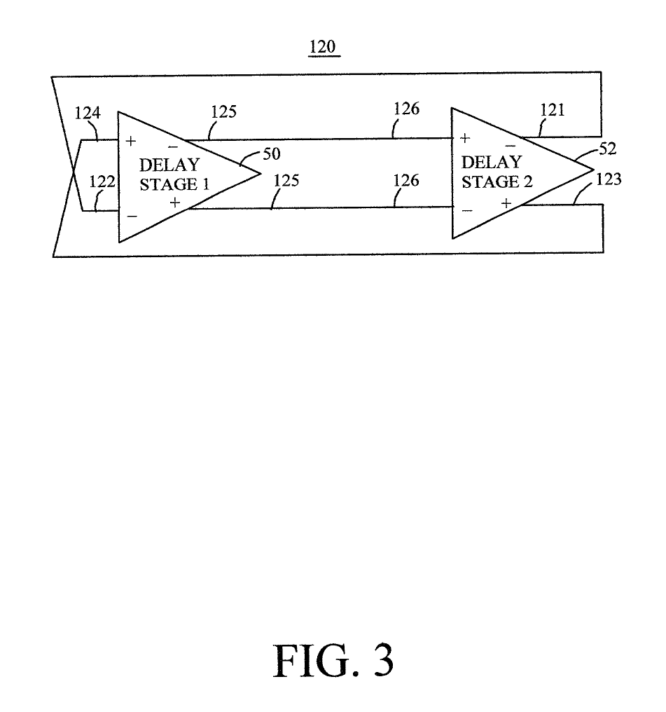

FIG. 3 includes a block diagram of a ring oscillator 120 formed of a first delay stage 50 coupled to a second delay stage 52 in a feedback arrangement. The first delay stage 50 may comprise the delay stage 100 of the FIG. 1 or the delay stage 110 of FIG. 2. The second delay stage 52 may comprise the delay stage 100 of FIG. 1 or the delay stage 110 of FIG. 2. The first output 121 of a second delay stage 52 is fed into a second input 122 of a first delay stage 50. The second output 123 of the second delay stage 52 is fed into a first input 124 of the first delay stage 50. Accordingly, second delay stage 52 provides positive feedback to the first delay stage 50 in addition to cascaded relationship between the output 125 of the first delay stage 50 and the input 126 of the second delay stage 52.

FIG. 4 illustrates a schematic diagram of a ring oscillator 130 in accordance with the invention. Although a ring oscillator 130 may be formed by cascading any embodiment of the delay circuits described herein, the ring oscillator of FIG. 4 incorporates the delay circuit 110 of FIG. 2. Like elements in FIG. 4 and FIG. 2 indicate like elements.

A ring oscillator 130 comprises a first output interface 64, a first delay stage 60 coupled to the first output interface 64, an second delay stage 62 coupled to the first delay stage 60, and a second output interface 66 coupled to the second delay stage 62. A ring portion 76 comprises the first delay stage 60 cascaded with a second delay stage 62. The ring portion 76 advantageously uses only two delay stages (60,62) to minimize jitter and the introduction of noise to the output voltages presented at the output terminals (68, 70, 72, and 74). Each of the delay stages comprises a cascade amplifier 18 having a first output and a second output for providing an output voltage between or approximately equal to at least one of the maximum rail voltage 10 and the minimum rail voltage 12. The output terminals include a primary terminal 68, a secondary output terminal 70, a tertiary output terminal 72, and a quaternary output terminal 74.

The first output interface 64 isolates the first delay stage 60 from at least one of the output terminals (68, 70, 72, and 74). The second output interface 66 isolates the second delay stage 62 from at least one of the output terminals (68, 70, 72 and 74). The first output interface 64 and the second output interface 66 produce a replica of the output signals for connection to other electronic devices and may introduce a phase shift (e.g., a one-hundred and eighty degrees phase shift) with respect to the output of the first delay stage 60 and the second delay stage 62, respectively.

The first output terminal 26 (a₁) of the first delay stage 60 is coupled to the second input terminal (d₂) of the second delay stage 62. The second output terminal 30 (b₁) of the first delay stage 60 is coupled to the first input terminal (c₂) of the second delay stage 62. The first input terminal 24 (c₁) of the first delay stage 60 is coupled to first output terminal (a₂) of the second delay stage 62. The second input terminal 28 (d₁) of the first delay stage 60 is coupled to the second output terminal (b₂) of the second delay stage 62.

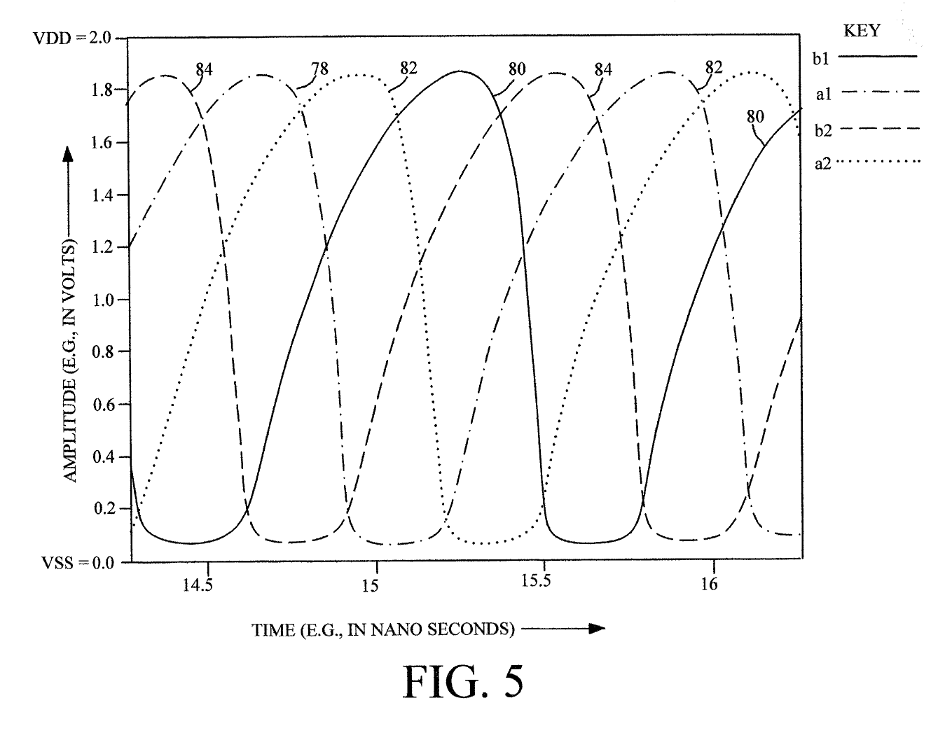

FIG. 5 shows illustrative output voltage signals in magnitude versus time for the voltage-controlled oscillator 130 of FIG. 4. Although the illustration of FIG. 4 contains specific voltages and time periods for the output signals, the present invention may be practiced under different voltages and time periods than those shown, while still falling within the scope of the claims. The vertical axis represents amplitude of the signal in voltage and the horizontal axis represents time. The voltage axis preferably spans the voltage range between a maximum rail voltage 10 (e.g., 1.8 volts) and a minimum rail voltage 12 (e.g., 0 volts).

Referring to FIG. 4 and FIG. 5, the first output interface 64 has a primary output terminal 68 and a secondary output terminal 70 for outputting a primary output signal 78 and a secondary output signal 80, respectively. The primary output signal 78 is preferably approximately one-hundred and eighty degrees out of phase with respect to the secondary output signal 80. The second output interface 66 has a tertiary output terminal 72 and a quaternary output terminal 74 for outputting a tertiary output signal 82 and a quaternary output signal 84, respectively. The tertiary output signal 82 is preferably one-hundred and eighty degrees out of phase with respect to the quaternary output signal 84. The primary output signal 78 may be ninety degrees out of phase with respect to the tertiary output signal 82. The secondary output signal 80 may be ninety degrees out of phase with respect to the quaternary output signal 84.

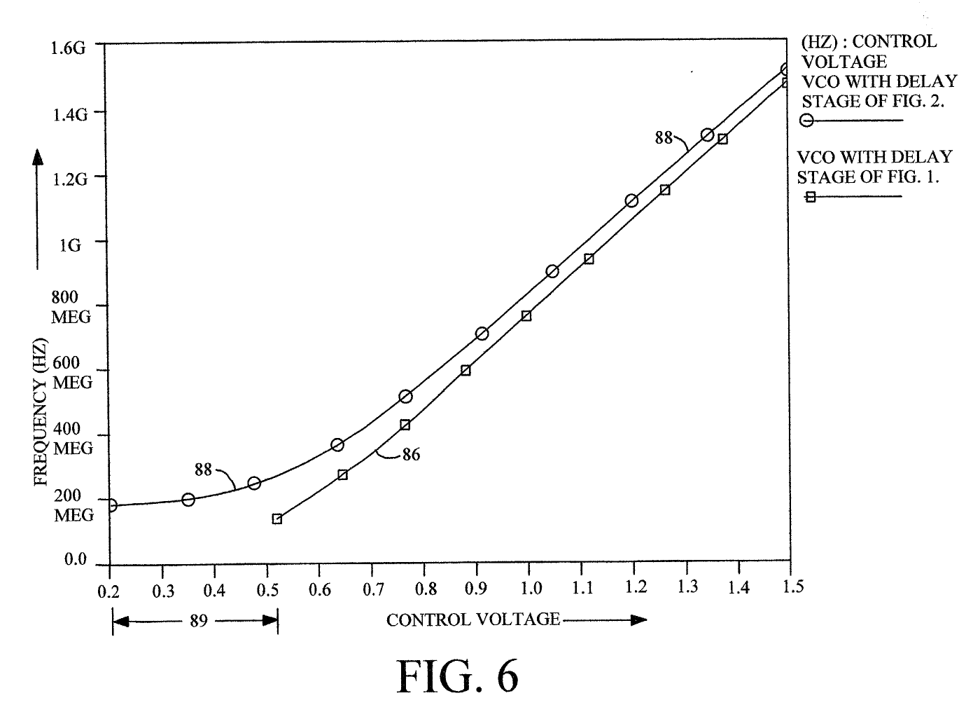

FIG. 6 shows a relationship between oscillation frequency of a voltage-controlled oscillator and the control voltage applied to the voltage-controlled oscillator for two different voltage-controlled oscillators. The vertical axis indicates frequency and the horizontal axis indicates the control voltage applied to the oscillator. Although the frequencies of the voltage-controlled oscillator and the control voltage are provided within illustrative ranges, the present invention may be practiced over virtually any frequency range or control voltage range over which semiconductor devices can operate.

A first voltage-controlled oscillator is indicated by the first response 86 or the generally linear response with the rectangular plot points, whereas the second voltage-controlled oscillator is indicated by the second response 88 or generally linear response with the circular plot points. The first voltage-controlled oscillator incorporates the delay stage of FIG. 1. The second voltage-controlled oscillator incorporates the delay stage of FIG. 2. The responses differ from one another in that the second response 88 of the second voltage-controlled oscillator operates over an extended control voltage range 89 in comparison to the first response 86 of the first voltage-controlled oscillator. In particular, the delay stage of FIG. 2 supports oscillation in the second voltage-controlled oscillator below a minimum threshold voltage (e.g., at approximately 0.51 volts as shown in FIG. 6).

The reduced jitter and improved immunity to noise that may be realized with the improved delay stage of the invention, can increase the reliability of reading, writing, and recording data in a prodigious assortment of electronic devices. For example, any of the delay stages and voltage controlled oscillators described herein may be applied to a pre-compensation write device of a hard-disk drive, a digital video disk device, a compact disk device, or a read/write channel of any other reading or writing device for reading or writing to a storage medium (e.g., an optical or magnetic storage medium).

The foregoing description describes several illustrative examples of the invention. Modifications, alternative arrangements and variations of these illustrative examples are possible and may fall within the scope of the invention. Accordingly, the following claims should be accorded the reasonably broadest interpretation which is consistent with the specification disclosed herein and that unduly limited by aspects of the preferred embodiments and other examples disclosed herein.

We claim:

1. A delay stage for inclusion in a semiconductor device, the delay stage comprising:
a first amplifier having a first input terminal and a supply terminal for receiving a minimum rail voltage;
a second amplifier having a second input terminal and a supply terminal for receiving the minimum rail voltage;
a cascade feedback amplifier coupled to the first amplifier and the second amplifier, the cascade feedback amplifier having a first output terminal and a second output terminal for providing an output voltage between or approximately equal to at least one of a maximum rail voltage and the minimum rail voltage; and
a current controller arranged to vary a resistive load presented to the cascade feedback amplifier, the resistive load associated with a current flowing to or from the maximum voltage rail.

2. The delay stage according to claim 1 wherein a maximum output voltage at one of the first output terminal and the second output terminal is approximately equal the maximum rail voltage less a drain-source drop of a transistor of the current controller.

3. The delay stage according to claim 1 wherein a minimum output voltage at one of the first output terminal and the second output terminal is approximately equal the minimum rail voltage plus a drain-source drop associated with one of the first amplifier and the second amplifier.

4. The delay stage according to claim 1 wherein the cascade amplifier comprises a primary transistor coupled to a secondary transistor such that a primary gate of the primary transistor is coupled to the second output terminal and a secondary gate of secondary transistor is coupled to the first output terminal.

5. The delay stage according to claim 1 wherein the current controller comprises at least one current-regulating transistor with a source-drain path coupled between the maximum voltage rail and the cascade amplifier.

6. The delay stage according to claim 1 further comprising a first oscillation-enhancing transistor having a control input coupled to the first input terminal, a second oscillation-enhancing transistor having a control input coupled to the second input terminal, and wherein a controlled path of at least one of the first oscillation-enhancing transistor and the second oscillation-enhancing transistor is coupled in parallel with the current controller between the maximum voltage rail the cascade amplifier.

7. The delay stage according to claim 1 wherein the cascade feedback amplifier comprises a primary transistor and a secondary transistor arranged to have opposite off-and-on states at the same time.

8. The delay stage according to claim 7 wherein the primary transistor and the second transistor comprise N-type metal oxide transistors.

9. The delay stage according to claim 8 wherein the current controller comprises P5 type metal oxide transistors.

10. The delay stage according to claim 1 wherein the first amplifier comprises an N-type metal oxide transistor having a gate as the first input terminal and a source as the supply terminal; and wherein the second amplifier comprises an N-type metal oxide transistor having a gate as the second input terminal and a source as the supply terminal.

11. A ring oscillator comprising;
a first delay stage; and
a second delay stage coupled to the first delay stage, each of said delay stages comprising a cascade amplifier having a first output terminal and a second output terminal for providing an output voltage between or approximately equal to at least one of the maximum rail voltage and the minimum rail voltage.

12. The ring oscillator according to claim 11, further comprising:
a first output interface for isolating the first delay stage from a primary output and a secondary output; and
a second output interface for isolating the second delay stage from a tertiary output and a quaternary output.

13. The oscillator according to claim 11 wherein a maximum output voltage at one of the first output terminal and the second output terminal is approximately equal the maximum rail voltage less a drain-source drop of a transistor of one of the first delay stage and the second delay stage

14. The oscillator according to claim 11 wherein a minimum output voltage at one of the first output terminal and the second output terminal is approximately equal the minimum rail voltage plus a drain-source drop of a transistor of one of the first delay stage and the second delay stage.

15. The oscillator according to claim 11 wherein the cascade amplifier comprises a primary transistor coupled to a secondary transistor such that a primary gate of the primary transistor is coupled to the second output terminal and a secondary gate of secondary transistor is coupled to the first output terminal.

16. The oscillator according to claim 11 wherein one of the delay stages comprises a current controller including at least one current-regulating transistor with a source-drain path coupled between the maximum voltage rail and the cascade amplifier.

17. The oscillator according to claim 11 further comprising a first oscillation-enhancing transistor having a control input coupled to the first input terminal, a second oscillation-enhancing transistor having a control input coupled to the second input terminal, and wherein a controlled path of at least one of the first oscillation-enhancing transistor and the second oscillation-enhancing transistor is coupled between the maximum voltage rail the cascade amplifier.

18. The oscillator according to claim 11 wherein the cascade feedback amplifier comprises a primary transistor and a secondary transistor arranged to have opposite off-and-on states at the same time.
